(19) United States
(12) Patent Application Publication
(10) Pub. No.: US 2017/0092777 A1
(43) Pub. Date: Mar. 30, 2017

(54) Semiconductor Device and Method

(71) Applicant: Infineon Technologies Austria AG, Villach (AT)

(72) Inventor: Martin Henning Vielemeyer, Villach (AT)

(21) Appl. No.: 15/279,140

(22) Filed: Sep. 28, 2016

(30) Foreign Application Priority Data
Sep. 29, 2015 (DE) 102015116473.6

(51) Int. Cl. H01L 29/786; H01L 29/267; H01L 29/66; H01L 29/40; H01L 29/417; H01L 29/08; H01L 29/49; H01L 29/06

(52) U.S. Cl. CPC H01L 29/78642; H01L 29/4916; H01L 29/267; H01L 29/0676; H01L 29/068; H01L 29/402; H01L 29/41741; H01L 29/41733; H01L 29/78696; H01L 29/0847; H01L 29/66462; H01L 29/2003

(57) ABSTRACT

In an embodiment, a semiconductor device includes a substrate, a plurality of columnar drift zones including a group III-nitride having a first conductivity type and a plurality of charge compensation structures. The columnar drift zones and the compensation structures are positioned alternately on a surface of the substrate.

### BACKGROUND

Today, transistors used in power electronic applications have typically been fabricated with silicon (Si) semiconductor materials. Common transistor devices for power applications include Si charge compensation power devices, Si Power MOSFETs, and Si Insulated Gate Bipolar Transistors (IGBTs). More recently, silicon carbide (SiC) power devices have been considered. Group III-N semiconductor devices, such as gallium nitride (GaN) devices, are now emerging as attractive candidates to carry large currents, support high voltages and to provide very low on-resistance and fast switching times.

### SUMMARY

In an embodiment, a semiconductor device includes a substrate, a plurality of columnar drift zones including a group III-nitride having a first conductivity type and a plurality of charge compensation structures. The columnar drift zones and the compensation structures are positioned alternately on a surface of the substrate.

In an embodiment, a vertical charge compensation group III-nitride-based field effect transistor includes a plurality of columnar transistor structures interleaved with a plurality of charge compensation structures. The plurality of columnar transistor structures each include a columnar drift zone comprising a group III-nitride having a first conductivity type and a columnar body zone having a group III-nitride comprising a second conductivity type opposing the first conductivity type. The columnar drift zone and the columnar body zone form a vertical drift path.

In an embodiment, a method includes epitaxially depositing a first columnar section of a group III nitride having a first conductivity type onto a substrate, epitaxially depositing a second columnar section of a group III nitride having a second conductivity type onto the first columnar section, the second conductivity type opposing the first conductivity type, and depositing a charge compensation structure adjacent the first columnar section or adjacent the second columnar section to produce a vertical charge compensation group III-nitride-based field effect transistor.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIG. 1 illustrates a vertical columnar group III-nitride based semiconductor device cell including a source contact and a gate contact on a top side of the device and a drain contact on the back side of the device according to an embodiment.

FIG. 2 illustrates a vertical columnar group III-nitride semiconductor device cell according to a further embodiment.

FIG. 3 illustrates a vertical columnar group III-nitride semiconductor device according to a further embodiment.

FIG. 4 illustrates a drain contact on top of the device and a source contact on the back side according to a further embodiment.

FIG. 5 illustrates a vertical columnar group III-nitride semiconductor device according to a further embodiment which includes a drain contact on top of the device and a source contact on the back side according to a further embodiment.

FIG. 6 illustrates a vertical columnar group III-nitride semiconductor device according to a further embodiment which includes a drain contact on top of the device and an n⁺-GaN section between the drain electrode and the drift section of the column.

FIG. 7 illustrates a vertical columnar group III-nitride semiconductor device according to a further embodiment which includes multiple vertical nano-columns of a drain down MISFET.

FIG. 8 illustrates a vertical columnar group III-nitride semiconductor device according to a further embodiment which includes multiple vertical nano-columns of a drain down MISFET including n⁺-GaN nano-column sections between the substrate with the drain electrode and the drift sections of the nano-columns.

FIG. 9 illustrates a vertical columnar group III-nitride semiconductor device according to a further embodiment which includes multiple vertical nano-columns of a drain down MISFET.

FIG. 10 illustrates a vertical columnar group III-nitride semiconductor device according to a further embodiment which includes multiple vertical nano-columns of a drain down MISFET including n⁺-GaN nano-column sections between the substrate with the drain electrode and the drift sections of the nano-columns.

FIG. 11 illustrates a top view of the vertical columnar group III-nitride semiconductor device of FIG. 9 and FIG. 10.

FIG. 12 illustrates an epitaxial growth of a first vertical columnar section of a GaN nano-column structure.

FIG. 13 illustrates an epitaxial growth of a second vertical columnar section of a GaN nano-column structure.

FIG. 14 illustrates an epitaxial growth of a third vertical columnar section of a GaN nano-column structure.

FIG. 15 illustrates a deposition of a dielectric layer around and on top of the GaN nano-column structure, and on top of the surface of the substrate as dielectric field plate layer.

FIG. 16 illustrates a deposition of a field plate material around the dielectric layer and around the first nano-column section of the GaN nano-column structure and on the dielectric layer of the substrate.

FIG. 17 illustrates a removal of the dielectric layer on top and around the GaN nano-column structure above the field plate.

FIG. 18 illustrates a deposition of a dielectric layer on top of the field plate and recessed GaN nano-column above the dielectric layer on the field plate.

FIG. 19 illustrates a deposition of a dielectric gate layer for an insulated gate contact on top and around the GaN nano-column, and on the dielectric layer of the field plate.

FIG. 20 illustrates a deposition of a gate-contact material around the dielectric gate layer and the second nano column section on the dielectric layer of the field plate.

FIG. 21 illustrates a vertical columnar group III-nitride based semiconductor device including a source contact and a gate contact on top of the device and a drain contact on the back side according to an embodiment.

FIG. 22 illustrates etching first windows in regular pattern in a hard mask for an implantation of a source contact on a substrate to produce a vertical columnar group III-nitride based semiconductor device including a drain contact on top of the device.

FIG. 23 illustrates an implantation of a highly doped layer in the opened windows of the hard mask to provide the source contact.

FIG. 24 illustrates a deposition of a hard mask material on the substrate surface of the windows to close the windows.

FIG. 25 illustrates an etching or reactive ion sputtering of openings in the hard mask material of smaller width than the first windows.

FIG. 26 illustrates a deposition of contact material at the bottom of the openings and a growth of highly doped GaN material of the second type in the openings.

FIG. 27 illustrates an epitaxial growth of a first vertical GaN nano-column section of the columnar structure including monocrystalline GaN including a second type of doping having a low doping level.

FIG. 28 illustrates an epitaxial growth of a second vertical GaN nano-column section of mono crystalline GaN including a first type of doping on the first vertical GaN nano-column section.

FIG. 29 illustrates a deposition of a dielectric gate layer around and on top of the GaN nano-column structure and a gate contact material on the dielectric layer.

FIG. 30 illustrates a deposition of a dielectric field plate layer on the gate contact material for field plate insulation.

FIG. 31 illustrates a deposition of a dielectric field plate layer around the GaN nano-column structure.

FIG. 32 illustrates a deposition of a field plate material on the dielectric field plate layer and around the second section of the nano-column.

FIG. 33 illustrates a deposition of a dielectric top layer on the device.

FIG. 34 illustrates a drain contact on top of the device and a source contact on the back side of the device according to a further embodiment.

FIG. 35 illustrates a vertical columnar group III-nitride semiconductor device according to a further embodiment which includes a drain contact on the top of the device and a source contact on the back side according to a further embodiment.

FIG. 36 illustrates a cross-sectional view of a portion of a columnar vertical charge compensated group III nitride-based field effect transistor cell.

FIG. 37 illustrates a cross-sectional view of a portion of a columnar vertical charge compensated group III nitride-based field effect transistor cell.

FIG. 38 illustrates a cross-sectional view of a portion of a columnar vertical charge compensated group III nitride-based field effect transistor cell.

### DETAILED DESCRIPTION

In the following detailed description, reference is made to the accompanying drawings, which form a part hereof, and in which is shown by way of example specific embodiments in which the invention may be practised.

It is to be understood that other embodiments may be utilized and structural or logical changes may be made without departing from the scope of the present invention. The following detailed description, thereof, is not to be taken in a limiting sense, and the scope of the present invention is defined by the appended claims.

A number of embodiments will be explained below. In this case, identical structural features are identified by identical or similar reference symbols in the figure(s). In the context of the present description, “lateral” or “lateral direction” should be understood to mean a direction or extent that runs generally parallel to the lateral extent of a semiconductor material or semiconductor layers. The lateral direction thus extends generally parallel to these surfaces or sides. In contrast thereto, the term “vertical” or “vertical direction” is understood to mean a direction that runs generally perpendicular to these surfaces or sides or layers and thus vertical to the lateral direction. The vertical direction therefore runs in the thickness direction of the semiconductor material or semiconductor layers.

In this regard, directional terminology, such as “top”, “bottom”, “front”, “back”, “leading”, “trailing”, etc., is used with reference to the orientation of the figure(s) being described. Because components of the embodiments can be positioned in a number of different orientations, the directional terminology is used for purposes of illustration and is in no way limiting.

Further, terms such as “first”, “second”, and the like, are also used to describe various elements, regions, sections, etc. and are also not intended to be limiting. Like terms refer to like elements throughout the description.

As employed in this specification, when an element such as a layer, region or substrate is referred to as being on or extending “onto” another element, it can be directly on or extend directly onto the other element or intervening elements may also be present. In contrast, when an element is referred to as being “directly on” or extending “directly onto” another element, there are no intervening elements present.

As used herein, the phrase “Group III-Nitride” refers to a compound semiconductor that includes nitrogen (N) and at least one Group III element, including aluminum (Al), gallium (Ga), indium (In), and boron (B), and including but not limited to any of its alloys, such as aluminum gallium nitride (AlₓGa₍₁₋ₓ₎), indium gallium nitride (In_{y}Ga_{(1-y)}N), aluminum indium gallium nitride (AlₓIn_{y}Ga_{(1-x-y)}N), gallium arsenide phosphide nitride (GaAsₐP_{b}N_{(1-a-b)}), and aluminum indium gallium arsenide phosphide nitride (AlₓIn_{y}Ga_{(1-x-y)}AsₐPbN_{(1-a-b)}), for example. Aluminum gallium nitride and AlGaN refers to an alloy described by the formula AlₓGa₍₁₋ₓ₎N, where 0<x<1.

Spatially relative terms such as “under”, “below”, “lower”, “over”, “upper” and the like are used for ease of description to explain the positioning of one element relative to a second element. These terms are intended to encompass different orientations of the device in addition to different orientations than those depicted in the figure(s).

As used herein, the terms “having”, “containing”, “including”, “comprising” and the like are open ended terms that indicate the presence of stated elements or features, but do not preclude additional elements or features. The articles “a”, an and the are intended to include the plural as well as the singular, unless the context clearly indicates otherwise.

It is to be understood that the features of the various embodiments described herein may be combined with each other, unless specifically noted otherwise.

In the embodiments described herein, a columnar transistor structure including a group III nitride semiconductor is provided. The columnar transistor structure has a vertical drift path and may be termed a columnar vertical transistor.

The columnar structure may include vertical “nano-columns” of a group III-nitride compound semiconductor material such as GaN, or mesas having a strip-like form. The nano-columns may be arranged in a regular array. The strip-like mesas may extend substantially parallel to one another. The lateral form of the nano-columns may be substantially circular, square, rectangular, or hexagonal, for example.

The columnar structure may be provided in place of a bulk group III-nitride semiconductor compound material. The columnar structure may be fabricated by epitaxial growth of the group III nitride material in the form of nano-columns or mesas. Bulk group III-nitride semiconductor compound material may have many slip-lines extending from the interface between a substrate, such as a silicon wafer, and overlying group III-nitride semiconductor compound due to lattice mismatch. The amount of slip-lines on the surface of a bulk group III-nitride semiconductor layer may be decreased by increasing the thickness of the layer, i.e. by a thicker epitaxially deposited layer. However, this increase in the thickness may lead to cracking upon cooling due to the large difference in thermal expansion coefficient. The use of the columnar form such as discrete nano-columns or discrete mesas of the group III-nitride semiconductor compound material may be used to provide a superior crystal quality.

For laterally small vertical columnar structures, mismatch and stress may be reduced as the lateral expansion of the group III-nitride semiconductor compound within the columnar structures is small. Consequently, the group III-nitride material can grow stress-lessly, without the need to relax in slip-lines or cracks.

In the drawings the columnar structures are described with reference to nano-columns. However, the nano-columns may also have a strip-like mesa structure having a cross-section corresponding to the columnar structure depicted in the drawings. Consequently, all the references to nano-columns can be taken to include mesas having a strip-like form.

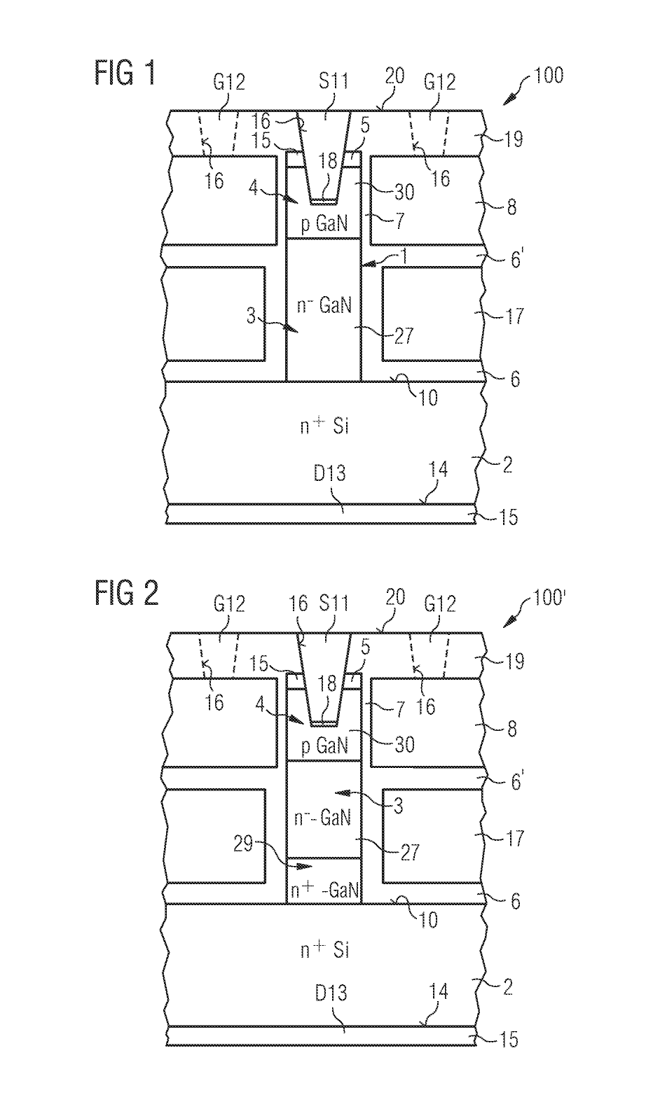

FIG. 1 illustrates a vertical nano-column group III-nitride based semiconductor device cell 100 including a source contact S11 and a gate contact G12 on top of the device cell and a drain contact D13 on the back side. The vertical nano-column group III-nitride based semiconductor device cell 100 may be a cell of a drain down MISFET (Metal Insulator Semiconductor Field Effect Transistor), for example.

The group III-nitride may be GaN. However, the group III-nitride is not limited to GaN and may include other group III-nitrides, for example AlGaN.

The vertical nano-column group III-nitride based semiconductor device cell 100 includes a single vertical GaN-nano-column 1, epitaxially grown on a surface 10 of a substrate 2. The substrate 2 may be n⁺-Si-substrate, a p⁺-Si substrate, a SiC substrate, a Si (111) substrate or a sapphire substrate. The base of the group II-nitride nano-column may be arranged directly on the substrate 2. However, the semiconductor device cell 100 is not limited to this arrangement. For example, one or more further layers may be arranged between the surface 10 of the substrate 2 and the base of the nano-column 1. For insulating substrates, such as sapphire, the second contact at the base of the nano-column is coupled to the rear surface of the substrate, for example by a conductive path such as a conductive via.

The single vertical GaN-nano-column 1 includes a first nano-column section 3 of low doped n⁻-GaN as a drift zone 27. A second nano-column section 4 of p-GaN provides a body zone 30 and a third nano-column section 5 of n⁺-GaN provides a contact material layer to the source electrode S11. The nano-column 1 is built up by epitaxial deposition of the first nano-column section 3 on the substrate 2, the second nano-column section 4 on the first nano-column section 3 and the third nano-column section 5 on the second nano-column section 4. The epitaxial deposition of the first nano-column section 3, second nano-column section 4 and third nano-column section 5 may be carried out in a single process step.

The drift zone 27 of this single vertical GaN-nano-column 1 is surrounded by a dielectric layer 6 of a field plate 17 and the body zone 30 is surrounded by a gate dielectric layer 7 and by a gate electrode material 8.

The source contact S11 and the gate contact G12 may be formed by depositing a dielectric top layer 19 over the top surface 20 of the structure, as is illustrated in FIG. 1. A planarization process may be performed on the dielectric top layer 19, for example by chemo-mechanical-polishing the dielectric top layer 19. Subsequently contact holes 16 for the source-contact S11 and the gate-contact G12 may be formed through the dielectric top layer 19, for example by etching, followed by implanting a contact transition layer 18 at the bottom of the contact holes 16 and introducing contact-material into the contact holes 16.

The drain contact D13 may be formed by depositing a contact material layer 15 on the back side 14 of the substrate 2, if the substrate is electrically conductive, for example an n⁺-doped silicon wafer. In embodiments, in which the substrate is electrically insulative, for example sapphire, the drain may be electrically coupled to the contact material layer 15 by an additionally conductive path such as a conductive path including a conductive via which extends through the thickness of the substrate.

FIG. 2 illustrates a further embodiment of the vertical nano-column group III-nitride semiconductor device cell 100′. The structure of this drain down MISFET cell according to this further embodiment is similar to the structure illustrated in FIG. 1. Components having the same functions as in FIG. 1 are characterised in the following figures by the same reference signs.

The nano-column structure 1 of the vertical nano-column group III-nitride semiconductor device cell 100′ includes four nano-column sections 3, 4, 5 and 29 instead of three nano-column sections 3, 4 and 5 as in the vertical nano-column group III-nitride semiconductor device cell 100 according to the first embodiment of FIG. 1.

The fourth nano-column section 29 is positioned between the substrate 2 and the first nano-column section 3. The fourth nano-column section 29 may be used to provide an epitaxially grown transition section close to the substrate 2 as a transition section between the lattice constant of the substrate 2 and the lattice constant of the n⁻-GaN section 3 and to provide relaxation. The fourth nano-column section 29 may include a low resistance material, such as n⁺-GaN and may be used to reduce the on-resistance of the drift zone 27. The highly doped n⁺-GaN of the fourth nano-column section 29 may function as a field stop zone for the space charge region of the PN junction between nano-column section 3 and nano-column section 4 when the device cell is reverse biased. The fourth nano-column section 29 may be used to allow the thickness of the field pate dielectric layer to be the same order of magnitude, or even greater, than the length of the drift zone.

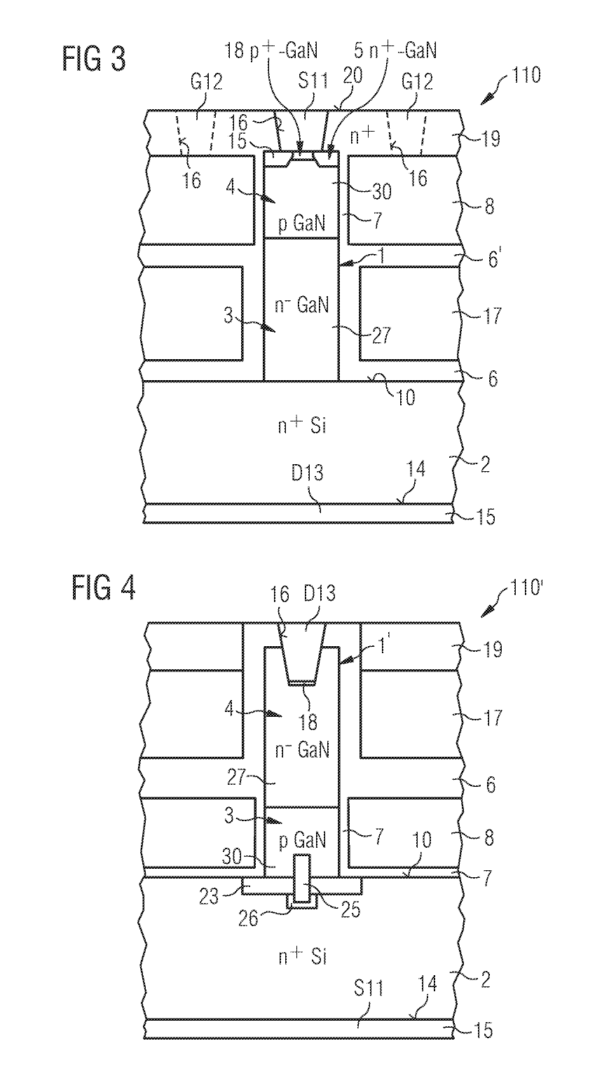

FIG. 3 illustrates a vertical nano-column group III-nitride semiconductor device cell 110 according to a further embodiment. A difference to the previous device cell 100 of FIG. 1 is that the source contact S11, the transition layer 18 and the contact material layer 15 are positioned on top of the second nano-column section 3 and not within the body zone 30 as in the embodiments illustrated in FIGS. 1 and 2.

FIGS. 4 to 6 illustrate a device cell 110′ in which the source S11 is arranged on the lower surface 14 of the substrate 2 and the drain D13 is arranged on the top side.

FIG. 4 illustrates a drain contact on top of a device cell 110′ and a source contact on the back side of a source down MISFET. This device cell 110′ includes a body zone 30 in contact with the substrate 2, in this particular embodiment, an n⁺-Si-substrate, and positioned below the drift zone 27. Here the epitaxial growth sequence is reversed compared to FIG. 1 to create this “source-down” MISFET cell. The nano-column section 3 provides a body zone 30 of the nano-column 1′ and is surrounded by a gate dielectric layer 7 and a layer of gate electrode material 8. The nano-column section 4 provides a drift zone 27 of the central nano-column 1′ and is surrounded by a field dielectric layer and a field plate 17.

The drain contact D13 on top of the device cell 110′ may be produced by depositing a dielectric top layer 19 onto the top surface 20 of the structure, by etching contact holes 16 for the drain-contact D13 through the dielectric top layer 19, by implanting a contact transition layer 18 at the bottom of the contact holes 16, by introducing conductive contact material into the contact holes 16 for the top drain contact. Optionally, the dielectric top layer 19 may be planarized, for example by chemical-mechanical-polishing. A contact material layer 15 may be deposited on the back side 14 on of the substrate 2 as a source contact S11.

A contact structure between the body zone 30 and the substrate 2 is provided which includes a highly doped surface layer 23 of the first doping type to form a source contact on the top surface 10 of the substrate 2, a source contact layer 26 of material, such as titanium silicide, to provide a source transition contact with highly doped GaN material 25 of the second doping type which extends from the source contact layer 26, through the surface layer 23 and into the body zone 30 to provide a connecting material between the source contact layer 26 and a first column section to be grown.

FIG. 5 illustrates a vertical nano-column group III-nitride semiconductor device cell 120 which includes a drain contact D13 on top of the device cell 120 and a source contact S11 on the back side. The device cell 120 may form a cell of a source down MISFET. This device cell 120 differs from the vertical nano-column group III-nitride semiconductor device cell 110′ according to the embodiment illustrated in FIG. 4, in that a drain contact D13 is provided on top of the device cell 120, which contacts a transition contact layer 18 arranged on top of the nano-column structure 1′.

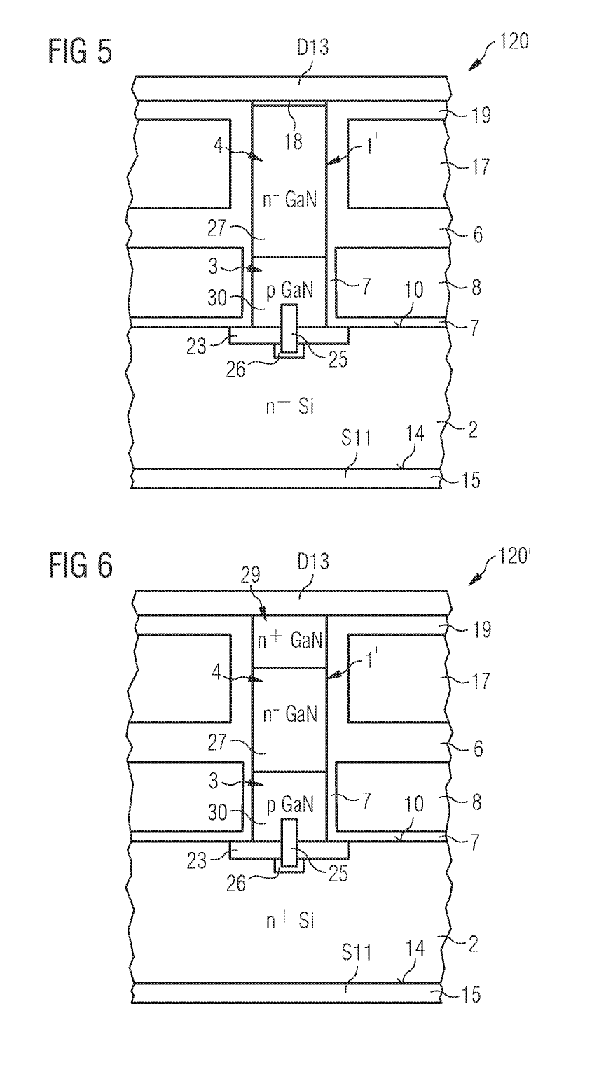

FIG. 6 illustrates a vertical nano-column group III-nitride semiconductor device cell 120′ according to a further embodiment which includes a drain contact D13 on top of the device cell 120′ and, additionally, an n⁺-GaN section 29 arranged between the drain electrode and the drift zone 27 of the nano-column 1′. The nano-column section 4 provides a drift zone 27, whilst the lower nano-column section 3 provides a body zone 30 of the device cell 120′.

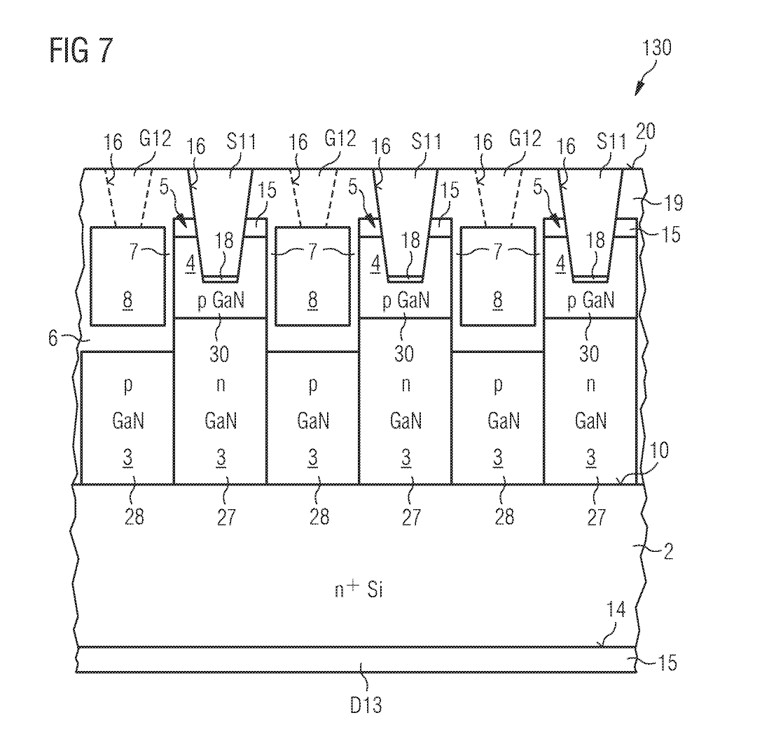

FIG. 7 illustrates a vertical nano-column group III-nitride semiconductor device 130 according to a further embodiment which includes multiple vertical nano-columns of a drain down MISFET. The drain down MISFET includes alternating nano-column drift-zones 27 of a group III-nitride of the first doping type and nano-columns of floating carrier compensation zones 28 of a group III-nitride of the second doping type. In this semiconductor device 130, one type of column can be grown by a patterned nano-column epitaxial growth technology and the other type of column may be formed like depositing bulk material in between the already grown nano-columns of the first type. Regions not forming an active part of the MISFET may be removed, for example by etching.

The gate electrode structure 8 may be similar to a vertical trench gate electrode structure and can be positioned on top of the floating nano-columns of the carrier compensation zones 28. A dielectric layer 6 is arranged on the floating carrier compensation zones 28 and on side faces of the drift zones 27 and body zones 30 which are arranged on the drift zones 28. The gate electrode structure surrounds a nano-columnar section of the body zone 30 which is positioned on top of the drift zone 27. Source contact metal alloys can be deposited into through holes 16 contacting a transition contact layer 18 within the body zones 30.

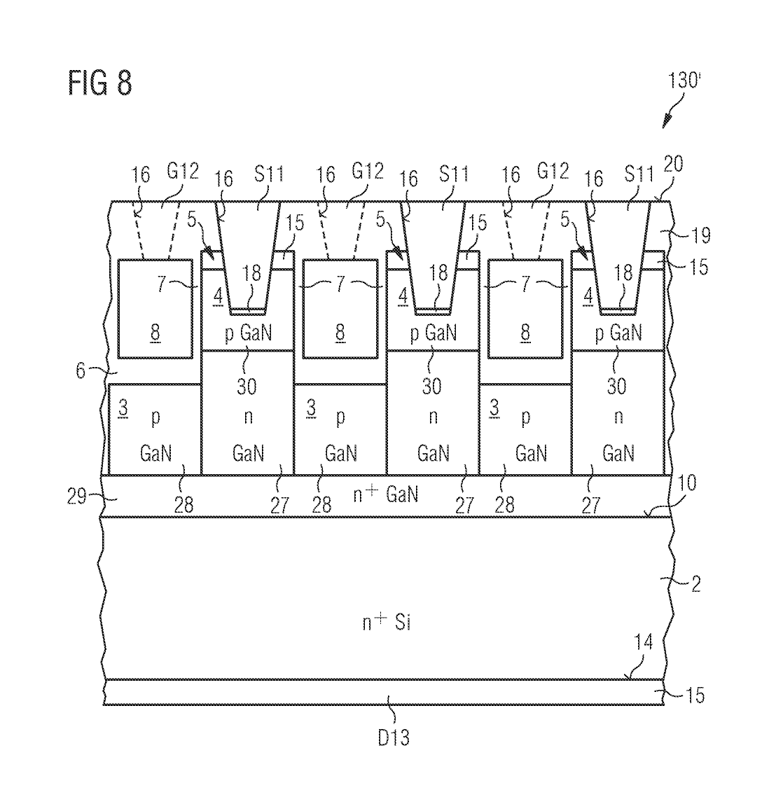

FIG. 8 illustrates a vertical nano-column group III-nitride semiconductor device 130′ according to a further embodiment which includes multiple vertical nano-columns of a drain down MISFET. This further embodiment differs from the embodiment of FIG. 7 in that it additionally includes an n⁺-GaN layer 29 epitaxially grown on the surface 10 of the substrate 2. The n⁺-GaN layer 29 extends under both the drift zones 27 and carrier compensation zones 28. The functions and advantages of the n⁺-GaN layer 29 are the same as discussed in the description of FIG. 2. A drain contact D13 is arranged on a rear surface of the substrate 2.

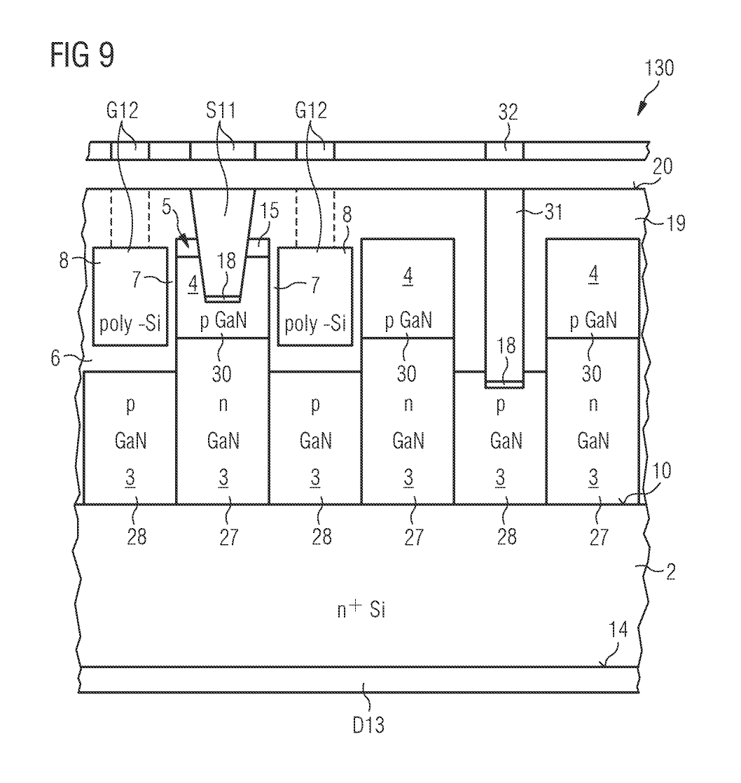

FIG. 9 illustrates a different cross section through the vertical nano-column group III-nitride semiconductor device 130 illustrated in FIG. 7 which includes multiple vertical nano-columns of a drain down MISFET. The nano-column carrier compensation zones 28 are non-floating and are in contact with a conductive strip 32 on top of the device surface 20 by a vertically extending connection area 31. The connection area 31 extends from the non-floating nano-columns carrier compensation zone 28 to the top surface 20 of the device.

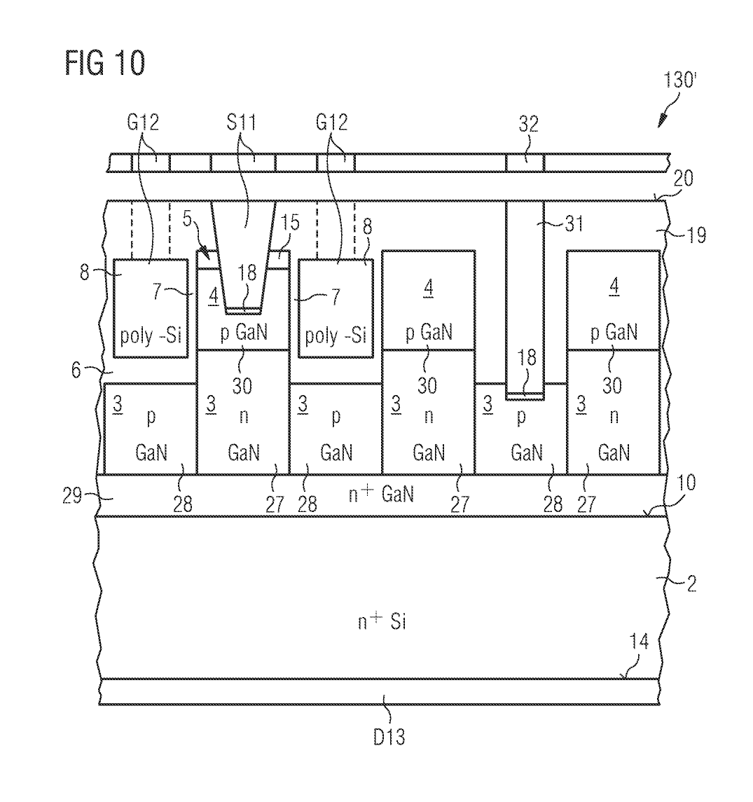

FIG. 10 illustrates a different cross section through the vertical nano-column group III-nitride semiconductor device 130′ according to FIG. 8. The nano-column carrier compensation zones 28 are non-floating. These non-floating nano-column carrier compensation zones 28 are in contact with a conductive strip 32 on top of the device surface 20 by a connection area 31. The connection area 31 extends from the non-floating nano-columns carrier compensation zone 28 to the top surface 20 of the device. This cross section plane view differs from FIG. 9 in that an n⁺-GaN layer 29 is epitaxially grown on the surface 10 of the substrate 2. A drain contact D13 is arranged on a rear surface of the substrate 2.

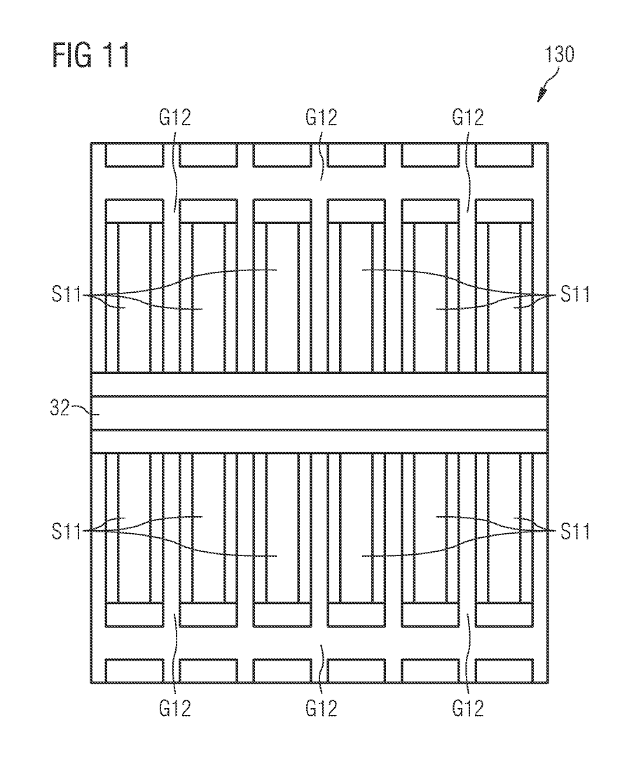

FIG. 11 illustrates a top view of the vertical nano-column group III-nitride semiconductor device as illustrated in FIG. 9 and FIG. 10. The contact structures of the embodiment of FIGS. 7 to 10 are illustrated in FIGS. 9 to 11. FIG. 11 illustrates a conductive strip 32 connecting the non-floating nano-column carrier compensation zones 28 of the semiconductor device illustrated in FIGS. 7 to 10. FIG. 11 also illustrates the source contact areas S11 and the gate contact regions G12.

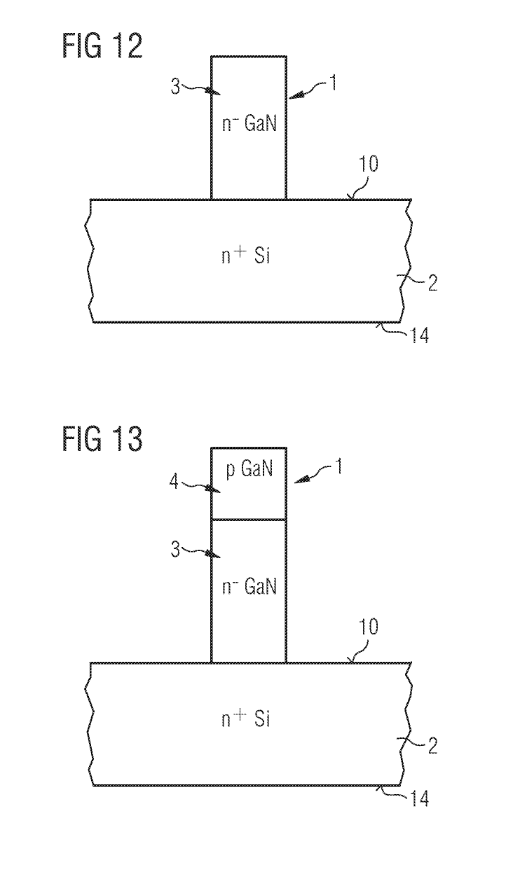

FIGS. 12 to 21 illustrate a method to produce a group III-nitride semiconductor device cell 100 with nano-columns for use in, for example, a MISFET (Metal Insulator Semiconductor Field Effect Transistor) with a drain down structure. The group III-nitride semiconductor device is illustrated in FIG. 1.

FIGS. 12 to 14 illustrate a method to produce a first vertical nano-column structure 1 for a group III-nitride semiconductor device 100 providing a drain down MISFET structure, such as that illustrated in FIG. 1. In other non-illustrated embodiments, the method for producing the nano-column structure 1 may be used to deposit the nano-column structure 1 on an n⁺-doped group III-nitride layer, such as the n⁺-GaN 29 illustrated in FIG. 2.

FIG. 12 illustrates an epitaxial grown first vertical nano-column section 3 of the GaN nano-column structure 1 including a first type of doping having a first low doping level. The first vertical column section 3 is epitaxially deposited on a top surface 10 of the substrate 2 which includes monocrystalline silicon highly doped with a first doping type, or another layer, for example a buffer layer. The nano-column section 3 may be epitaxially grown and may be one of a plurality of non-column sections arranged in a regular pattern. The regular pattern may be defined by lithography. However, other methods may be used to provide a regular pattern.

Since GaN nucleates on Si, but usually not on SiOₓ or SiN_{y} if the conditions are not suitably selected, it is possible to apply a “nucleation stop-layer” as a hard mask and to pattern it by means of lithography. This nucleation stop-layer can be used to define where the nano-column sections 3 are grown later on a suitable silicon substrate 2. The nano-column sections 3 may be grown by an epitaxial lateral overgrowth technique (ELOG).

A nucleation layer may be produced by depositing a layer onto the substrate 2 and structuring this layer with lithography to produce nanometer small seeds or seed regions. A very thin deposited metallic layer, for example a gold layer may be used, patterned by lithography to small nano dots of metal or gold on the substrate surface. However, the growth atmosphere differs locally at the liquid gold metal-droplets due to an elevated temperature, leading to nucleation of seeds in this small region. The droplets can stay on top of the columns and are not incorporated into the growing nano-column material of group III-nitride semiconductors.

A nucleation layer may be produced by adjusting the deposition parameters slightly away from the parameters, with which GaN can be grown on the Si-substrate, such that GaN is not grown on the bare Si-substrate.

In an embodiment, the nano-column section may be grown under conditions in which a group III-nitride material only grows on a group III-nitride, but not on the substrate. If a bulk group III-nitride layer is etched away everywhere except in regions in which the nano-columns should grow, the remaining GaN-residues or regions may also be used to provide a regular pattern of nucleation seeds or seed regions.

After the seed positions are defined, the epitaxial growth of the first vertical nano-column section 3 of the GaN nano-column structure 1 can be started.

After terminating the epitaxial growth of the first vertical nano-column section 3, for example including n-doped GaN, a second vertical nano-column section 4 of a GaN nano-column structure 1 is epitaxially deposited on the first vertical nano-column section 3. As is illustrated in FIG. 13, the second vertical nano-column section 4 is grown up on top of the first vertical GaN nano-column section 3. The second vertical nano-column section 4 includes a second type of doping having a second doping level, for example p doped GaN. The second type of doping is complementary or opposite to the first type of doping. For example, the first type of doping may be n type and the second type of doping may be p type or vice versa.

This stack of complementary doped group III-nitride nano-columns can be produced by switching the doping of the first vertical nano-column section 3 to the doping of the second vertical nano-column section 4. This may be achieved by adjusting the growth conditions and/or dopant material for the group III-nitride material, for example. The dopant may be introduced after the growth of the first nano-column section 3 and/or second nano-column section 4 or during the growth of the first nano-column section 3 and/or second nano-column section 4.

During the production of a subsequent nano-column section on a previously formed nano-column section, the material of the subsequent nano-column section may be deposited on the sidewall of the previously formed nano-column section. If undesired, this material deposited on the side wall of the previously formed nano-column section may be removed. Alternatively, a further layer may be deposited onto the side wall of the previously formed nano-column section including a material which prevents the adhesion of the material of the subsequent nano-column section.

For example, during production of the second vertical nano-column section 4, some material of the second vertical nano-column section 4 having the second type of doping may be deposited on the sidewall of the first nano-column section 3. In this case, this material may be removed. For example, the material having the second type of doping at a second doping level may be removed from the side wall of the first nano-column section 3 using tilted reactive ion etching (RIE) and conditioning of the sidewall surface of the first column section 3.

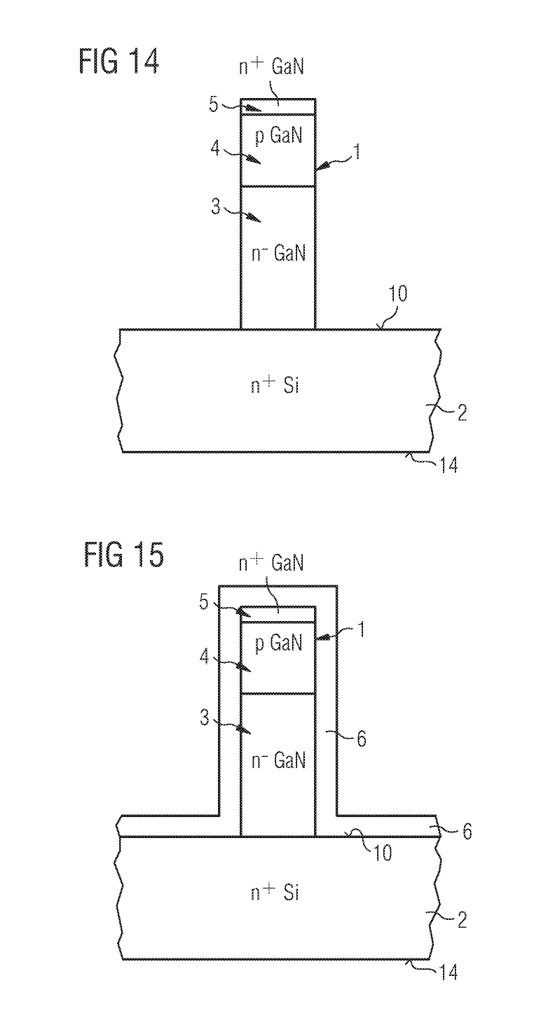

A highly doped GaN layer 5 may then be epitaxially grown on top of the nano-column section 4, as illustrated in FIG. 14. This stack may be considered to have a structure similar to the mesa of a dual gate trench MOSFET. The nano-column structure 1 may include GaN of the first doping type for the nano-column section 3 on the substrate 2 as a drift zone, a lightly doped GaN of the second doping type for a nano-column section 4 on top of nano-column section 3 as a body zone and the GaN layer 5 which is highly doped with the first doping type may be epitaxially grown on the nano-column section 4 to provide a source contact zone.

In some non-illustrated embodiments, a further GaN layer, which is highly doped with the first doping type, may be grown on the surface 10 of the substrate and the first nano-column section 3 grown on the further GaN layer.

FIGS. 15 to 21 illustrate a method for producing a vertical nano-column group III-nitride semiconductor device in the form of a drain down MISFET using the vertical GaN nano-column structure 1 illustrated in FIG. 14.

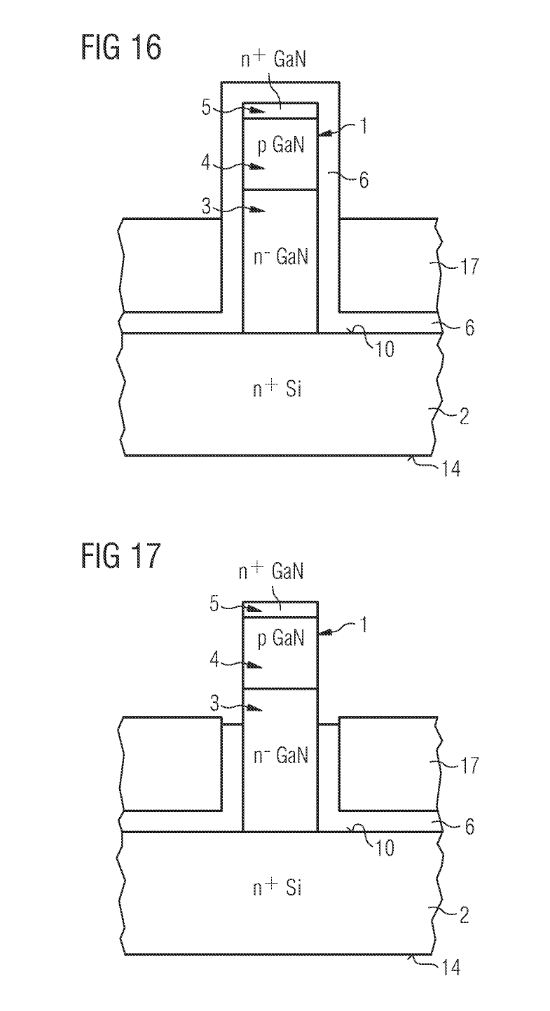

As is illustrated in FIG. 15, an insulating dielectric field plate layer 6 can be deposited around nano-column structure 1, i.e. on side faces of the nano-column structure 1, on top of the GaN nano-column structure 1 and on top of the surface 10 of the substrate 2. A field plate material may be deposited on the dielectric field plate layer 6 to create a field plate 17 surrounding the first nano-column section 3. This is shown in FIG. 16.

The field dielectric layer 6 should be able to withstand very high electrical fields. In FIG. 16 the height of the dielectric field plate layer is less than the height of the n⁻-GaN drift layer so that the specific breakdown voltage of the field dielectric should be higher than the breakdown voltage of the n⁻-GaN drift layer. This may be achieved by selecting the thickness of the dielectric field plate layer 6 depending on its dielectric constant. For example, for SiO₂, the dielectric field plate layer 6 may be provided with a thickness that is greater than the thickness of the gate dielectric layer. In further non-illustrated embodiments, a low resistance layer, for example an n⁺-GaN zone, may be provided under the drift zone 27 as is also illustrated in FIG. 2 to provide compensation between the different lattice constants and relaxation.

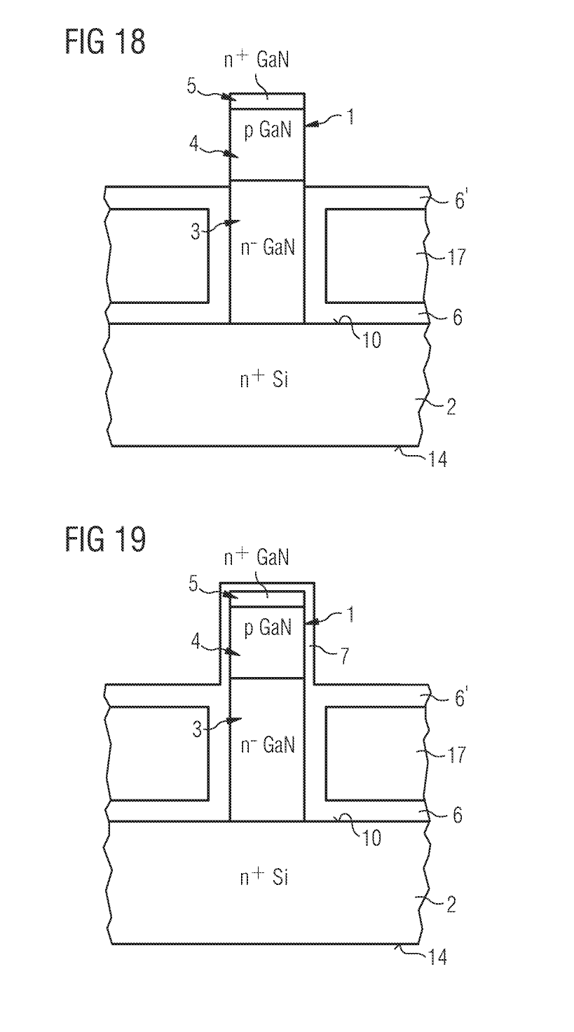

Thereafter, material of the dielectric field plate layer may be removed, for example by etching from the top and around the GaN nano-column structure 1 above the field plate 17, such that the body zone provided by the second nano-column section 3 and the source transfer contact zone provided by the highly doped epitaxial grown GaN layer 5 are exposed, as is illustrated in FIG. 17. A dielectric field plate layer 6′ material may be deposited on top of the field plate, as is illustrated in FIG. 18.

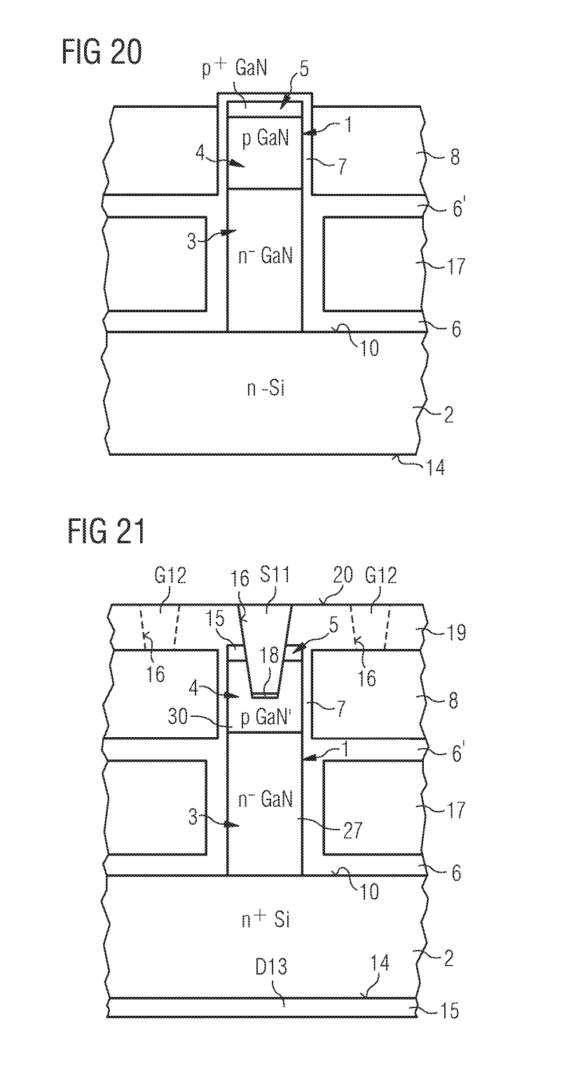

FIG. 19 illustrates depositing a dielectric gate layer 7 for an insulated gate contact on top and on side faces of the second GaN nano-column section 4 and of the third GaN nano-column section 5 as well as on the dielectric field plate layer 6′. The thickness of the dielectric gate layer 7 may be significantly smaller than the thickness of the dielectric field plate layers 6 and 6′. A gate contact material 8 is deposited on the dielectric gate layer 7 surrounding the body zone provided by the second nano-column section 4 and on the dielectric field plate layer 6′, as is illustrated in FIG. 20.

A source contact S11 and a gate contact G12 are arranged on a top surface 20 of the device and a drain contact D13 is arranged on the back side 14 of the substrate 2 to provide a drain down MISFET structure as illustrated in FIG. 21 and in FIG. 1. The source contact S11 and the gate contact G12 may be formed by depositing a dielectric top layer 19 over the top surface 20 of the structure, as is illustrated in FIG. 20. A planarization process may be performed on the dielectric top layer 19, for example by chemical mechanical polishing the dielectric top layer 19 and subsequently contact holes 16 for the source-contact S11 and the gate-contact G12 may be formed through the dielectric top layer 19, for example by etching, followed by implanting a contact transition layer 18 at the bottom of the contact holes 16 and introducing contact-material into the contact holes 16. The drain contact D13 may be formed by depositing a contact material layer 15 throughout the back side 14 of the substrate 2.

The first conductivity type material can include n doped GaN and the second conductivity type material may include p doped GaN in this first embodiment illustrated in FIG. 21 and FIG. 1. The gate electrode material 8 and the field plate material may include highly doped polycrystalline silicon. The dielectric field plate layer 6′ arranged on top of the field plate 17 can be produced by oxidizing the highly doped polycrystalline silicon providing the field plate material. The contact material in the contact holes 16 as well as the contact material of the contact material layer 15 on the back side surface 14 of the substrate 2 may include one or more metals or metal alloys.

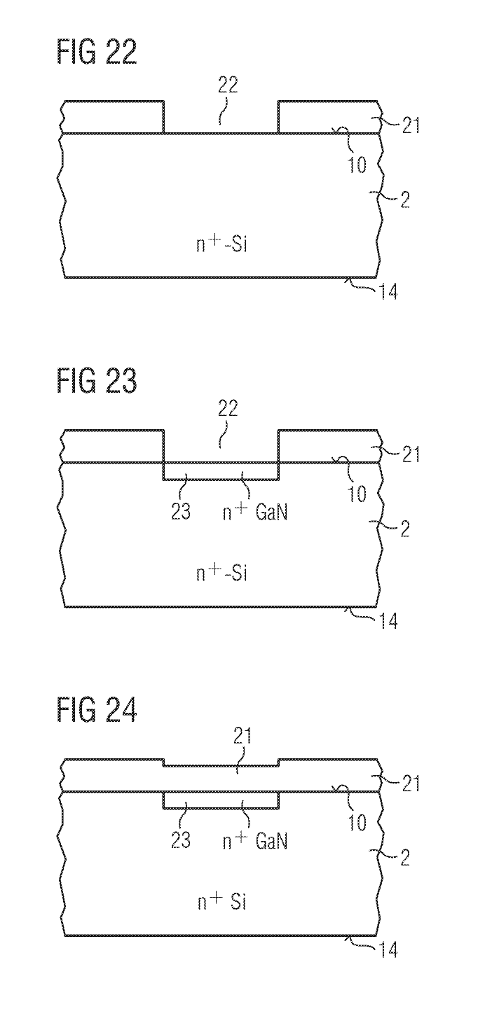

FIGS. 22 to 26 illustrate a method to provide a vertical nano-column structure 1′ for a group III-nitride semiconductor compound device, for example based on GaN, which includes a source down MISFET structure.

As is illustrated in FIG. 22, a hard mask layer 21 is applied to a substrate 2. The substrate 2 is a Si substrate 2 which is highly doped with a first doping type, for example an n⁺-doped Si substrate. The hard mask layer 21 may be selectively etched to provide a regular pattern of recessed windows on a top surface 10 of the substrate 2. A highly doped surface layer 23 of the first doping type is implanted through the regularly patterned windows to form a source contact on the top surface 10 of the substrate 2, as is illustrated in FIG. 23. The windows 21 are closed by depositing hard mask material onto the windows 21, as is illustrated in FIG. 24.

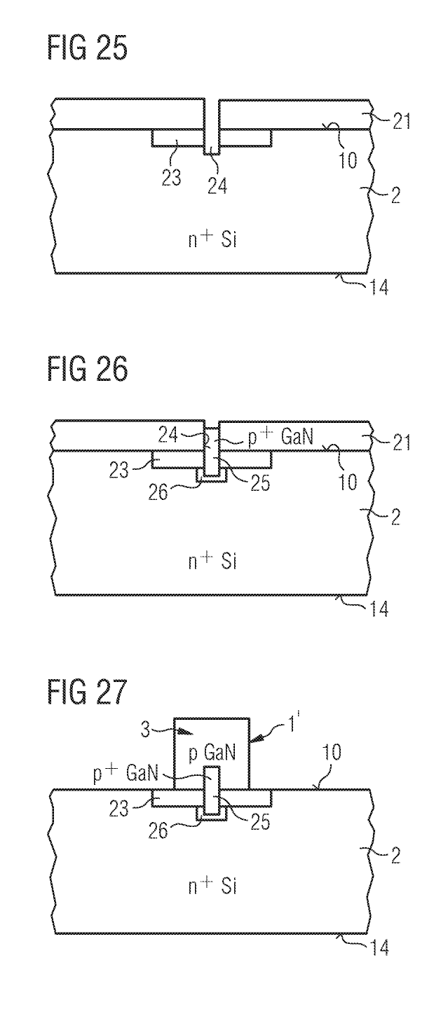

Thereafter, a pattern of nano-sized openings 24 may be formed, for example by etching, into the hard mask material through the closed windows and through the implanted surface layer 23 and into the silicon substrate material. The nano-sized openings 24 have a smaller width than the windows, as is illustrated in FIG. 25. A source contact layer 26 of material, such as titanium silicide, may be deposited on the bottom of the openings 24 to provide a source transition contact. The openings 24 may be filled by depositing highly doped GaN material 25 of the second doping type into the openings 24, as is illustrated in FIG. 26, to provide a connecting material between the source contact layer 26 and a first column section to be grown. Furthermore, this doped GaN material 25 can supply an arrangement of GAN nucleation seeds for epitaxial growth of mono crystalline first nano-column sections 3 after etching the hard mask layer, as is illustrated in FIG. 27. Optionally an n⁺-GaN source layer 23 can be first grown on the top surface 10 of the substrate 2 and the layer 3 of p GaN may be grown on the n⁺-GaN source layer 23.

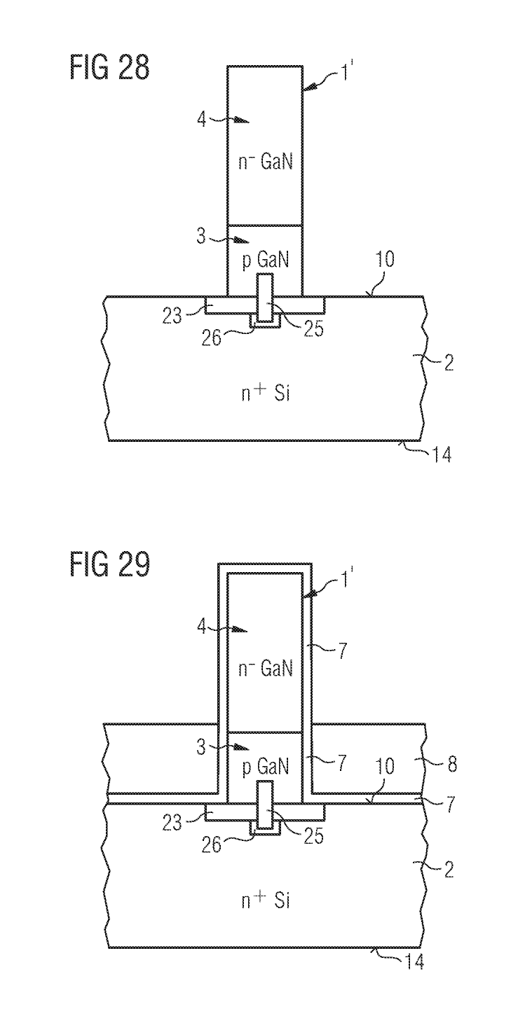

FIG. 28 illustrates an epitaxial growth of a nano-column structure 1 of two mono-crystalline nano-column sections including a first nano-column section 3 as a body zone including the second doping type of low doped GaN. A second nano-column section 4 is epitaxially grown on the first nano-column section 3 as a drift zone which includes the first doping type. The first nano-column section 3 provides a connection to the source transfer contact 26 illustrated in FIG. 23.

FIGS. 29 to 34 illustrate a method to provide a vertical nano-column group III-nitride semiconductor device having a source down MISFET structure based on the vertical GaN nano-column structure 1′ according to FIG. 28. Firstly, a dielectric layer 7 is deposited on side faces and on top of the GaN nano-column structure 1′ as well as on top of the top surface 10 of the substrate 2. The dielectric layer 7 has a thickness suitable for an insulated gate contact. The thickness of the dielectric layer 7 may be greater in regions on the substrate 2 than on the side faces of the GaN nano-column structure 1′ in order to reduce the parasitic capacitance in this region. A gate contact material 8 is deposited on the dielectric layer 7 such that it is arranged on side faces of the body zone provided by the first nano-column section 3 of the GaN nano-column structure 1′ as well as on the dielectric gate layer 7 on top of the surface 10 of the substrate 2, as is illustrated in FIG. 19.

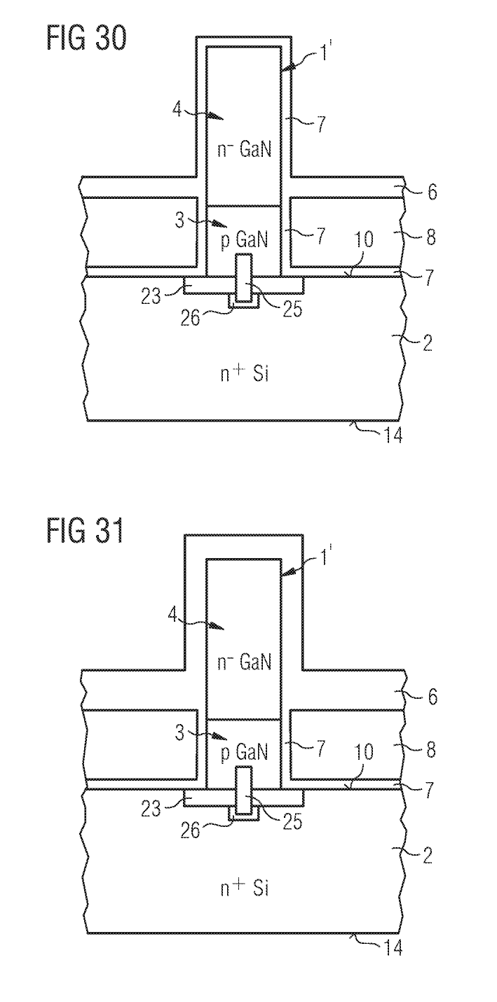

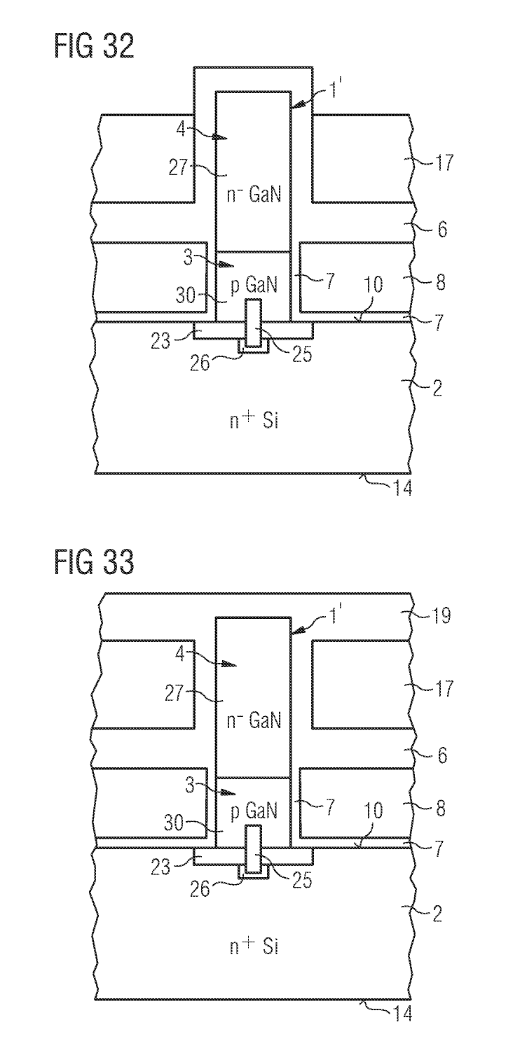

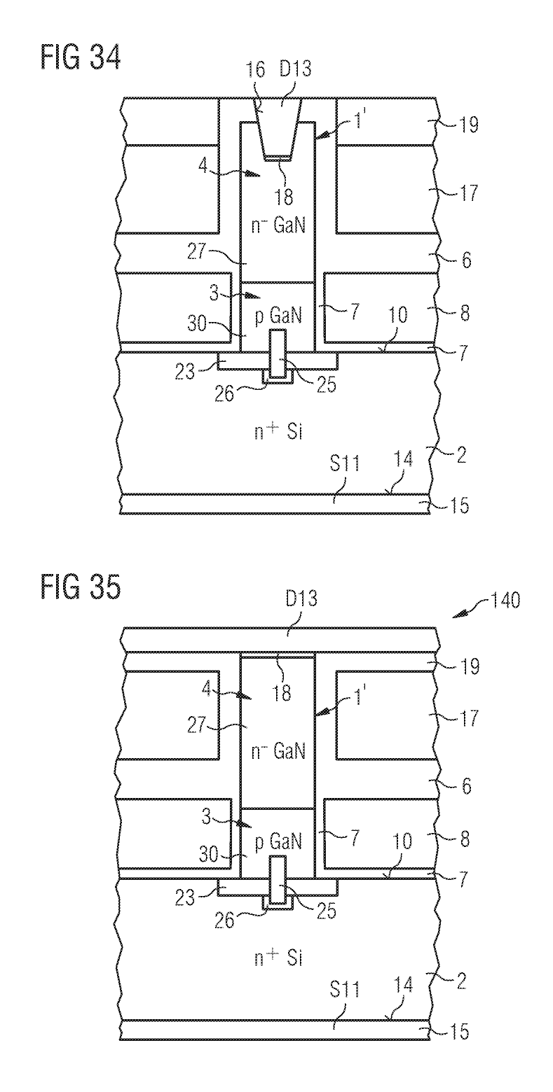

A dielectric field plate layer 6 may be formed on top of the gate contact, for example by oxidizing the gate contact material if the gate contact includes highly doped poly silicon, for example, as is illustrated in FIG. 30. A dielectric layer is deposited on side faces of the GaN nano-column structure 1′ for an insulating field plate layer 6, as is illustrated in FIG. 31. Then a field plate material is deposited on the dielectric field plate layer 6 to provide a field plate 17 around the drift zone, as is illustrated in FIG. 32. A dielectric top layer 19 is deposited on the top of nano-column structure 1′ and the field plate 17, as is illustrated in FIG. 33. The dielectric top layer 19 may be planarized, as is illustrated in FIG. 33, for example by chemical-mechanical-polishing. Finally, a drain contact D13 is provided on the top surface 20 of the device and a source contact S11 on the back side 14 of the substrate 2 to produce a source down MISFET structure as illustrated in FIG. 34.

The drain contact D13 and the source contact S11 may be produced by depositing a dielectric top layer 19 on the top surface 20 of the structure, as is illustrated in FIG. 33, chemical mechanical polishing the dielectric top layer 19, etching contact holes 16 for the drain-contact D13 through the dielectric top layer 19, implanting a contact transition layer 18 at the bottom of the contact holes 16, filling the contact holes 16 with contact-material and depositing a contact material layer 15 throughout the back side 14 of the substrate 2 as a source contact S11.

FIG. 35 illustrates a vertical nano-column group III-nitride semiconductor device 140 according to a further embodiment. This further embodiment differs from the vertical nano-column group III-nitride semiconductor device according to the embodiment illustrated in FIG. 4, in that a drain contact D13 is provided on top of the device, contacting a transition contact layer 18 on top of the nano-column structure 1′.

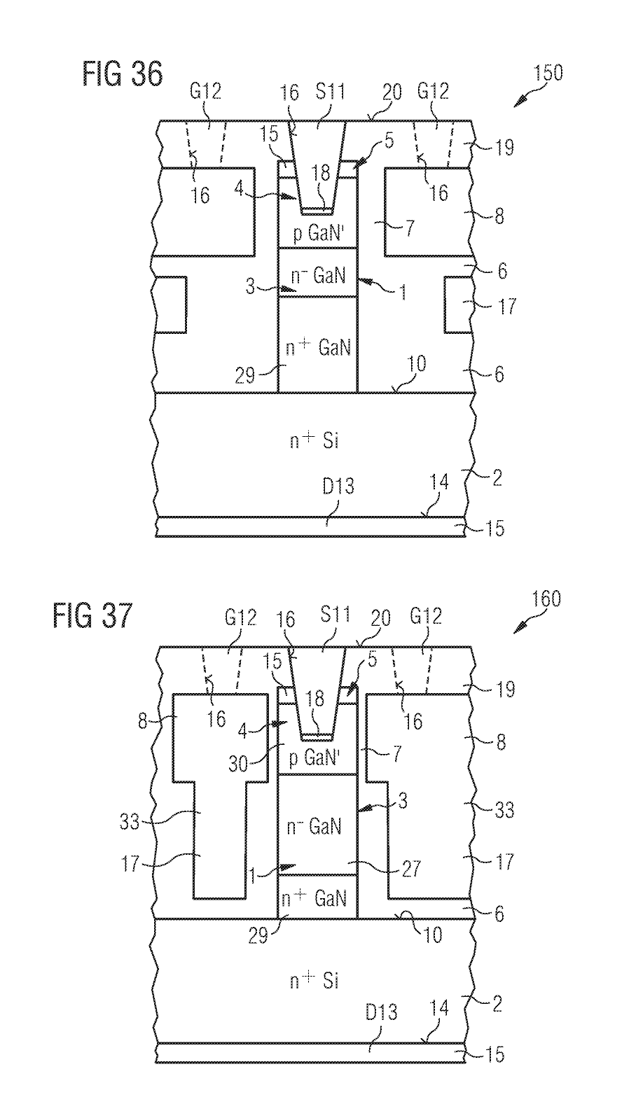

FIG. 36 illustrates a cross-sectional view of a portion of a columnar vertical charge compensated group III nitride-based field effect transistor cell 150. The columnar structure 1 may be formed by epitaxial growth of the group III nitride, such as GaN, on the substrate 2. The columnar structure 1 may include nano-columns arranged in a regular array or mesas having a strip like arrangement separated by strip like trenches. The columnar structures 1 are arranged alternately with a charge compensation structure such as a conductive field plate 17.

The columnar structure 1 may include a first transition section 29 epitaxially grown on the surface 10 of the substrate 2. The transition section 29 may include a group III nitride highly doped with a first conductivity type. A drift zone section 3 is arranged on the first transition section 29 and lightly doped with the first conductivity type. A body section 4 is arranged on the drift zone section 3, which is doped with a second conductivity type. A highly doped section 15 is arranged on the body zone section 4. The drift zone section 3, the body zone section 4 and the highly doped section 15 may each be epitaxially grown. A contact structure may extend through the highly doped layer 15 into the body zone section 4.

The columnar structure 1 may be embedded in a dielectric layer 6. A field plate 17 and a gate electrode 8 may be arranged in a stack between neighbouring columnar structures 1. The gate electrode 8 is arranged adjacent the body zone section 4 and the conductive field plate 17 may be arranged adjacent the drift zone section 3 and uppermost portion of the transition section 29. The thickness of the drift one region 3 may be less than the thickness of the dielectric layer between the side face of the drift zone section 3 and a conductive field plate 17.

The thickness of the dielectric layer 6 between the surface 10 of the substrate 2 and the field plate 17 and the thickness of the dielectric layer between the side face of the drift zone section 3 and the field plate 17 may be greater than a width of the drift zone section 3. This arrangement may be used in embodiments in which the specific breakdown voltage of the dielectric material is less than that of the group III nitride. For example, this arrangement may be used if a dielectric material 6 is silicon dioxide and the group III nitride is GaN.

In the embodiments illustrated above, the gate electrode 8 and the field plate 17 are separated from one another by a portion of the dielectric layer 6. However, in some embodiments, the gate 8 and the field plate 17 may be integrated with one another so that a single electrode is positioned between neighbouring columnar vertical transistor structures 1. This columnar vertical transistor structure may be drain down or source down.

FIG. 37 illustrates a cross-sectional view of a portion of a columnar vertical charge compensated group III nitride-based field effect transistor cell 160.

The columnar structure 1 of the group III nitride may be formed by epitaxial growth of the group III nitride, such as GaN, on the substrate 2. The columnar structure 1 may include nano-columns 1 arranged in a regular array or mesas having a strip like arrangement separated by strip like trenches. The columnar structures 1 are arranged alternately with a charge compensation structure such as a conductive field plate 17.

The columnar structure 1 may include a first transition section 29 epitaxially grown on the surface 10 of the substrate 2. The transition section 29 may include a group III nitride highly doped with a first conductivity type. A drift zone section 3 is arranged on the first transition section 29 and lightly doped with the first conductivity type. A body section 4 is arranged on the drift zone section 3, which is doped with a second conductivity type. A highly doped section 15 is arranged on the body zone section 4. The drift zone section 3, the body zone section 4 and the highly doped section 15 may each be epitaxially grown to form the nano-column 1. A contact structure may extend through the highly doped layer 15 into the body zone section 4.

The columnar structure 1 may be embedded in a dielectric layer 6. In this embodiment, a single electrode 33 is arranged between neighbouring columnar structures 1. The single electrode 33 provides an integrated field plate 17 and gate electrode 8. The single electrode 33 has a T-type shape such that the upper horizontal portion is spaced at a smaller distance from the body zone section 4 than the distance between the side face of the drift zone section 3 and the side face of the vertical portion of the T-type shape. The horizontal portion can be considered to provide the gate electrode 8 and the vertical portion can be considered to provide the field plate.

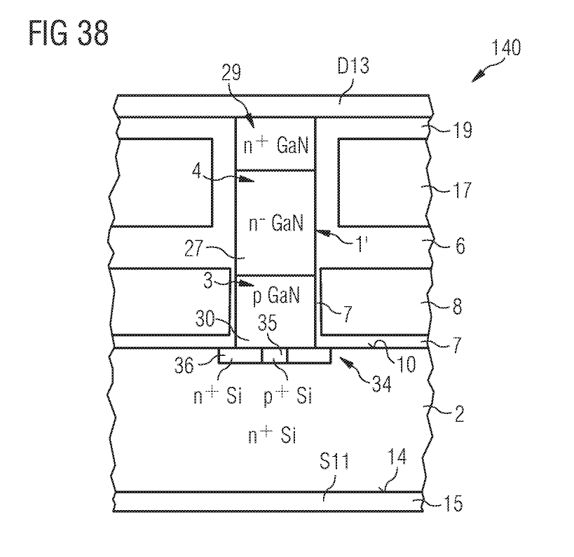

FIG. 38 illustrates a vertical nano-column group III nitride semiconductor device cell 140 which includes a drain contact D13 on top of the device cell 140 and a source contact S11 on the back side. The device cell 140 may form a cell of a source down MISFET. This device cell 140 differs from the vertical nano-column group III nitride semiconductor cell 110′, 120, 120′ according to the embodiments illustrated in FIGS. 4 to 6, in the form of the body contact to the substrate 2. The body contact 34 is formed in the substrate 2, for example by masked implantation. The body contact 34 includes a central p⁺ doped Si region 35 and an n⁺ doped Si region 36 arranged at the base of the nano-column 1′. The n⁺ doped Si region 36 laterally surrounds the p⁺ doped Si region 35. The body contact 34 may be used as an alternative to the structure 25 illustrated in FIGS. 4 to 6 for example.

In the specific embodiments described above, the conductivity type may be reversed, i.e. n-doped regions may be replaced by p-doped regions and p-doped regions may be replaced by n-doped regions, in order to provide a p-type FET structure.

In the drawings, the illustrated substrate 2 is an n⁺-Si-substrate. However, the substrate 2 is not limited to an n⁺-S-substrate and may include other materials, such as a p⁺-Si substrate, a SiC substrate, a Si (111) substrate or a sapphire substrate.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A semiconductor device, comprising
a substrate;
a plurality of columnar drift zones comprising a group III-nitride comprising a first conductivity type; and
a plurality of charge compensation structures, the columnar drift zones and the compensation structures being positioned alternately on a surface of the substrate.

2. The semiconductor device of claim 1, further comprising a columnar body zone arranged on the columnar drift zones, the columnar body zone comprising a group III-nitride comprising a second conductivity type opposite the first conductivity type.

3. The semiconductor device of claim 2, further comprising a source contact zone comprising a group III-nitride that is highly doped with the first conductivity type, the source contact zone being arranged on the columnar body zone.

4. The semiconductor device of claim 3, further comprising:
a gate dielectric layer on side faces of the columnar body zone; and
a gate electrode material on the dielectric layer.

5. The semiconductor device of claim 2, further comprising a drain contact arranged on a rear surface of the substrate.

6. The semiconductor device of claim 2, further comprising a highly doped zone arranged between the columnar drift zones and the substrate.

7. The semiconductor device of claim 1, further comprising a columnar body zone arranged between the columnar drift zones and the substrate, the columnar body zone comprising a group III-nitride comprising a second conductivity type.

8. The semiconductor device of claim 7, further comprising a drain contact zone arranged on the columnar drift zones.

9. The semiconductor device of claim 7, further comprising:
a gate dielectric layer on side faces of the columnar body zone; and
a gate electrode material on the dielectric layer.

10. The semiconductor device of claim 7, further comprising a source contact arranged on a rear surface of the substrate.

11. The semiconductor device of claim 1, wherein the group III-nitride comprises GaN.

12. The semiconductor device of claim 1, wherein the substrate comprises <111> silicon.

13. The semiconductor device of claim 4, wherein the gate electrode material comprises highly doped polycrystalline-silicon.

14. The semiconductor device of claim 1, wherein the charge compensation structures comprise columnar zones comprising a group III nitride comprising a second conductivity type arranged on side faces of the columnar drift zones.

15. The semiconductor device of claim 1, wherein the charge compensation structures comprise an insulating dielectric layer arranged on side faces of the columnar drift zones and a conductive field plate arranged on the dielectric layer.

16. A method, comprising:
epitaxially depositing a first columnar section of a group III nitride having a first conductivity type onto a substrate;
epitaxially depositing a second columnar section of a group III nitride having a second conductivity type onto the first columnar section, the second conductivity type being opposite the first conductivity type; and
depositing a charge compensation structure adjacent the first columnar section or adjacent the second columnar section so as to form a vertical charge compensation group III-nitride-based field effect transistor.

17. The method of claim 16, wherein the first columnar section forms a drift zone of a vertical group III-nitride-based semiconductor device and the charge compensation structure is deposited adjacent the first columnar section.

18. The method of claim 16, wherein depositing the charge compensation structure comprises depositing an insulating dielectric layer on side faces of the first columnar section and a conductive layer on the insulating dielectric layer so as to form a field plate.

19. The method of claim 18, further comprising:
depositing a gate dielectric layer on side faces of the second columnar section, the gate dielectric layer having a first thickness smaller than a second thickness of the insulating dielectric layer; and
depositing a gate electrode material on the dielectric gate layer adjacent the second columnar section, the second columnar section providing a body zone of the vertical group III-nitride-based semiconductor device.

20. The method of claim 19, wherein the second thickness of the insulating dielectric layer is greater than a width of the drift zone.

21. The method of claim 16, wherein depositing the charge compensation structure comprises depositing a group III nitride having a second conductivity type onto side faces of the first columnar section.

22. The method of claim 16, further comprising:
epitaxially growing a group III nitride layer that is highly doped with a first conductivity type on a surface of the substrate; and
epitaxially depositing the first columnar section on the highly doped group III nitride layer.

23. The method of claim 19, further comprising:
depositing a third columnar section on the first columnar section, the third columnar section comprising a group III nitride highly doped with the first conductivity type;
depositing a dielectric layer onto the third columnar section and onto the gate electrode material;
forming a first contact hole through the dielectric layer, through the third columnar section and into the second columnar section;
forming a second contact hole through the dielectric layer to the gate electrode material;
introducing contact material into the first and second contact holes so as to form a source contact and a gate contact of the vertical group III-nitride-based semiconductor device; and
depositing a contact material layer on a back side surface of the substrate so as to form a drain contact of the group III-nitride-based semiconductor device.

24. The method of claim 16, wherein the first columnar section forms a body zone of a vertical group III-nitride-based semiconductor device and the charge compensation structure is deposited adjacent the second columnar section.

25. The method of claim 24, further comprising:
depositing a gate dielectric layer on side faces of the first columnar section; and
depositing gate electrode material onto the gate dielectric layer.

26. The method of claim 25, wherein depositing the charge compensation structure comprises depositing an insulating dielectric layer on side faces of the second columnar section and a conductive layer on the insulating dielectric layer so as to form a field plate, wherein the insulating dielectric layer has a thickness greater than a thickness of the gate dielectric layer.

27. The method of claim 24, further comprising:
epitaxially growing a group III nitride layer that is highly doped with a first conductivity type on a surface of the Substrate; and
epitaxially depositing the first columnar section on the highly doped group III nitride layer.

28. The method of claim 24, further comprising:
depositing contact material on the second column section and forming a drain contact; and
depositing a contact material layer on a back side surface of the substrate so as to form a source contact.

29. A vertical charge compensation group III-nitride-based field effect transistor, comprising a plurality of columnar transistor structures interleaved with a plurality of charge compensation structures, the plurality of columnar transistor structures each comprising a columnar drift zone comprising a group III-nitride having a first conductivity type and a columnar body zone having a group III-nitride having a second conductivity type opposite the first conductivity type, the columnar drift zone and the columnar body zone providing a vertical drift path.
